(19) United States
(12) Patent Application Publication
(10) Pub. No.: US 2024/0348217 A1
(43) Pub. Date: Oct. 17, 2024

(54) ASYMMETRIC OPERATIONAL AMPLIFIER

(71) Applicant: SEMICONDUCTOR COMPONENTS INDUSTRIES, LLC, Scottsdale, AZ (US)

(72) Inventors: David KROLAK, Brno (CZ); Pavel HORSKY, Brno (CZ)

(73) Assignee: SEMICONDUCTOR COMPONENTS INDUSTRIES, LLC, Scottsdale, AZ (US)

(21) Appl. No.: 18/526,088

(22) Filed: Dec. 1, 2023

Related U.S. Application Data
(60) Provisional application No. 63/495,985, filed on Apr. 13, 2023.

(51) Int. Cl. H03F 3/45

(52) U.S. Cl. CPC H03F 3/4508; H03F 2203/45266

(57) ABSTRACT

An asymmetric amplifier circuit is disclosed. The amplifier circuit includes an input-stage circuit and an output-stage circuit. The input stage circuit can include a first terminal with a first input impedance and a second terminal with a second input impedance different than the first input impedance. The input-stage circuit may be configured to receive a first input signal on the first input terminal, receive a second input signal on the second input terminal, and generate a first amplified signal and a second amplified signal using the first input signal and the second input signal. The output-stage circuit may be configured to asymmetrically combine the first amplified signal and the second amplified signal to generate an output signal.

### CROSS-REFERENCE TO RELATED APPLICATIONS

The present application claims the benefit of U.S. Provisional Application No. 63/495,985, titled “Asymmetrical Operational Transconductance Amplifier,” filed Apr. 13, 2023, the content of which is incorporated by reference herein in its entirety for all purposes.

### TECHNICAL FIELD

This disclosure is related to electronic circuits and, more particularly, to operational amplifier circuits.

### BACKGROUND

Many computer and analog systems, including Bluetooth, Wi-Fi, software define radio, and the like, employ amplifier circuits in a variety of applications. For example, in some computer systems, an amplifier circuit may be used to create a version of an input signal from an antenna with a larger amplitude. Some amplifier circuits may be single-ended, while other amplifier circuits may have two inputs and generate an output signal whose value is proportional to a difference between two input signals received via the two inputs. Some amplifier circuits, referred to as operational transconductance amplifier circuits, or simply “OTAs,” generate an output current based on its input signals as opposed to an output voltage.

### SUMMARY

Various embodiments of an amplifier circuit are disclosed. Broadly speaking, an amplifier circuit includes an input-stage circuit and an output-stage circuit. The input stage circuit can include a first terminal with a first input impedance and a second terminal with a second input impedance different than the first input impedance. The input-stage circuit may be configured to receive a first input signal on the first input terminal, receive a second input signal on the second input terminal, and generate a first amplified signal and a second amplified signal using the first input signal and the second input signal. The output-stage circuit may be configured to asymmetrically combine the first amplified signal and the second amplified signal to generate an output signal.

### BRIEF DESCRIPTION OF THE DRAWINGS

For a detailed description of example embodiments, reference will now be made to the accompanying drawings in which:

FIG. 1 is a block diagram of an embodiment of an asymmetric amplifier circuit.

FIG. 2 is a block diagram of an embodiment of an input-stage circuit for an asymmetric amplifier circuit.

FIG. 3 is a block diagram of an embodiment of an output-stage circuit for an asymmetric amplifier circuit.

FIG. 4 is a block diagram of an embodiment of a voltage reference circuit.

FIG. 5 is a block diagram of an embodiment of an anti-saturation circuit.

FIG. 6 is a flow diagram of an embodiment of a method for operating an asymmetric amplifier circuit.

Many of the electrical connections in the drawings are shown as direct couplings having no intervening devices, but are not expressly stated as such in the following description. Nevertheless, this paragraph shall serve as antecedent basis in the claims for referencing any electrical connection as “directly coupled” for electrical connections shown in the drawing with no intervening device(s).

### Definitions

Various terms are used to refer to particular system components. Different companies may refer to a component by different names—this document does not intend to distinguish between components that differ in name but not function. In the following discussion and in the claims, the terms “including” and “comprising” are used in an open-ended fashion and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

“A,” “an,” and “the,” as used herein, refers to both singular and plural referents unless the context clearly dictates otherwise. By way of example, “a processor” programmed to perform various functions refers to one processor programmed to perform each and every function, or more than one processor collectively programmed to perform each of the various functions.

In relation to electrical devices (whether stand alone or as part of an integrated circuit), the terms “input” and “output” refer to electrical connections to the electrical devices, and shall not be read as verbs requiring action. For example, a differential amplifier (such as an operational amplifier) may have a first differential input and a second differential input, and these “inputs” define electrical connections to the operational amplifier, and shall not be read to require inputting signals to the operational amplifier.

“Assert” shall mean creating or maintaining a first predetermined state of a Boolean signal. Boolean signals may be asserted high, or with a higher voltage, and Boolean signals may be asserted low, or with a lower voltage, at the discretion of the circuit designer. Similarly, “de-assert” shall mean creating or maintaining a second predetermined state of the Boolean signal, opposite the asserted state.

“FET” shall mean a field-effect transistor, such as a junction-gate FET (JFET), a metal-oxide semiconductor field-effect transistor (MOSFET), Fin field-effect transistor (FinFET), or gate-all-around field-effect transistor (GAAFET).

“Closing” in reference to an electrically controlled switch (e.g., a FET) shall mean making the electrically controlled switch conductive. For example, closing a FET used as an electrically controlled switch may mean driving the FET to a full conductive state.

“Opening” in reference to an electrically controlled switch (e.g., a FET) shall mean making the electrically controlled switch non-conductive.

“Controller” or “controller circuit” shall mean, alone or in combination, individual circuit components, an application specific integrated circuit (ASIC), a microcontroller with controlling software, a reduced-instruction-set computing (RISC) circuit with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

Amplifier circuits may be used in a variety of applications in electronic devices and computer systems. One such application is in the generation of reference voltages that are invariant to changes in power supply voltage levels and temperature. Such reference voltages are employed by other analog or mixed-signal circuits within an electronic device or computer system. For example, a reference voltage may be used to bias a different amplifier circuit, or be used as part of a comparator for an analog-to-digital converter circuit.

Various circuit topologies may be used to implement a voltage reference circuit. One such circuit topology is a Brokaw bandgap reference circuit which uses a difference between the base-emitter voltages of two bipolar devices with different emitter areas. To properly bias the two bipolar devices, the respective collector terminals of the bipolar devices, which are coupled to corresponding inputs of an amplifier circuit, are coupled to a power supply node via corresponding resistors.

Differences in the capacitances of the two circuit nodes coupled to the collector terminals of the bipolar devices result in different time constants for the two circuit nodes. The different time constants can result in different transient responses on the two circuit nodes in response to noise coupled into the two circuit nodes from the power supply node. The different transient responses can cause power supply noise that would otherwise be common-mode noise, to appear as differential noise at the inputs of the amplifier circuit. Such differential noise can result in unwanted variation in the value of the reference voltage.

The variation in the time constants of the two nodes can be at least partially remediated through the addition of capacitors coupled to the two nodes. This solution, however, can have an undesirable effect on the size of the voltage reference circuit. Moreover, the additional capacitors may not vary over process, power supply voltage, and temperature, as the nodal capacitance values further limiting the effectiveness of the solution. The embodiments described herein may provide techniques for making the respective input impedances of the input terminals of an amplifier circuit asymmetric. By using an amplifier circuit with asymmetric input impedances, the time constants of the collector terminal circuit nodes of a voltage reference circuit can be adjusted without the area penalty associated with the addition of capacitors.

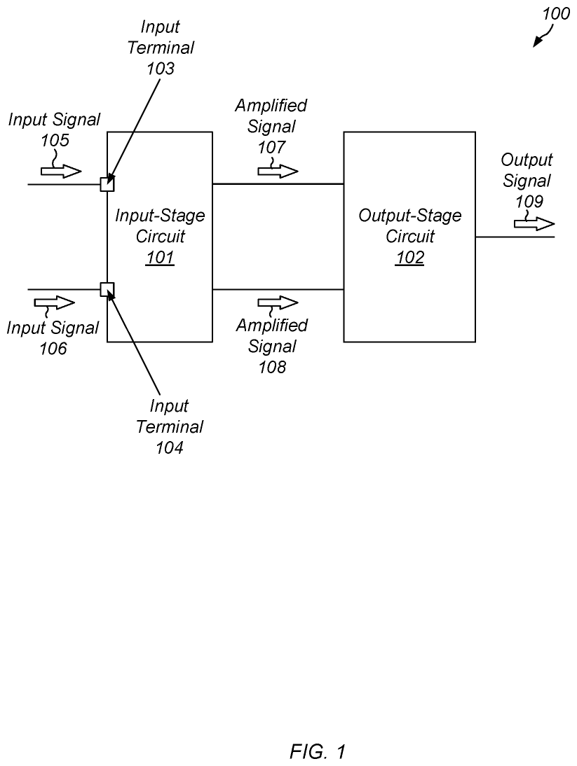

FIG. 1 shows block diagram of an embodiment of an asymmetric amplifier circuit. As illustrated, amplifier circuit 100 includes input-stage circuit 101 and output-stage circuit 102.

Input-stage circuit 101 includes input terminal 103 and input terminal 104. In some embodiments, input terminal 103 is referred to as a “non-inverting” input of amplifier circuit 100, while input terminal 104 is referred to as an “inverting” input of amplifier circuit 100. In various embodiments, input-stage circuit 101 is configured to receive input signal 105 via input terminal 103, and receive input signal 106 via input terminal 104. In some embodiments, an input impedance of input terminal 103 may be different than an input impedance of input terminal 104. The difference between the input impedance of input terminal 103 and the input impedance of terminal 104 may be based, at least in part, on respective time constants associated with circuit nodes coupled to input terminal 103 and input terminal 104.

In various embodiments, input-stage circuit 101 is configured to generate amplified signal 107 and amplified signal 108 using input signal 105 and input signal 106, respectively. As described below, input-stage circuit 101 may include a differential transistor pair that is configured to generate amplified signals 107 and 108 using input signals 105 and 106, and different physical characteristics of the transistors included in the differential transistor pair may be used to achieve a desired difference in the respective input capacitances of input terminals 103 and 104.

Output-stage circuit 102 is configured to asymmetrically combine amplified signal 107 and amplified signal 108 to generate output signal 109. As used herein, to asymmetrically combine two signals refers to applying different gains, either a voltage gain or a current gain, to the two signals in order to generate an output signal. It is noted that output signal 109 may either be a current or a voltage.

In some embodiments, output-stage circuit 102 may be coupled to input-stage circuit 101 in a cascode arrangement. As described below, output-stage circuit 102 may, in various embodiments, include a current-mirror circuit that includes transistors with different physical characteristics. In some cases, the difference in the physical characteristics of the transistors in the current-mirror circuit may be the same as the difference in the physical characteristics of the transistors included in the differential pair.

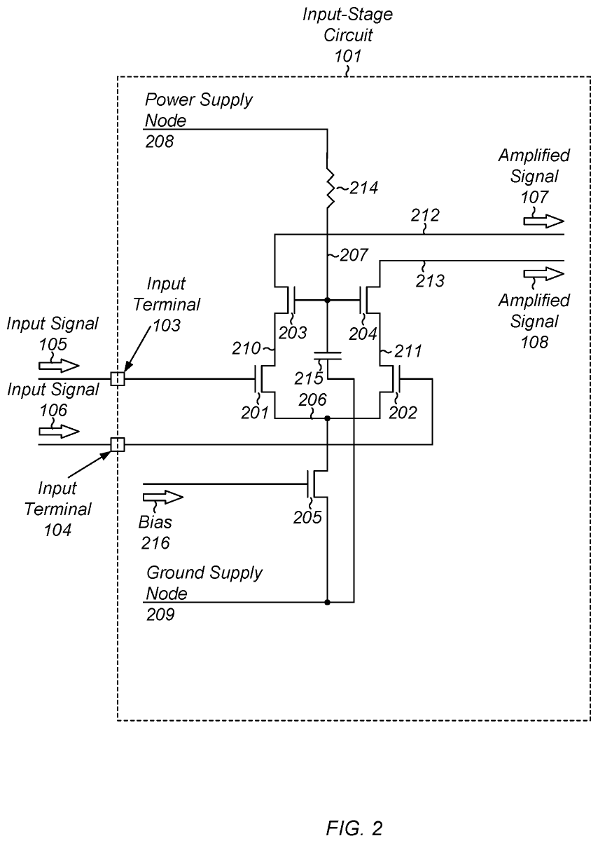

Turning to FIG. 2, a block diagram of an embodiment of input-stage circuit 101 is depicted. As illustrated, input-stage circuit 101 includes transistors 201-205, resistor 214, and capacitor 215.

Transistor 201 is coupled between node 210 and node 206. A control terminal of transistor 201 is coupled to input terminal 103. In a similar fashion, transistor 202 is coupled between node 211 and node 206, with its control terminal coupled to input terminal 104. In various embodiments, transistors 201 and 202 form a “differential pair” which is configured to generate amplified signal 107 and amplified signal 108.

In a traditional differential pair, the transistors included in the pair have the same physical size in order to have similar electrical characteristics. In the present embodiment, however, transistors 201 and 202 have different physical sizes in order to generate different impedance values for input terminals 103 and 104. In some cases, both the length and width of transistors 201 and 202 may be different. Alternatively, the lengths of transistors 201 and 202 may be the same, while the widths of the transistors are different. In some cases, transistors 201 and 202 may be implemented using multiple transistors, with a common width, coupled together in parallel. In such cases, the number of transistors used may be referred to as a number of “legs.” In the present embodiment, transistor 201 may have a different number of legs than transistor 202. For example, transistor 201 may have three legs, while transistor 202 may have only two legs.

The differential pair formed by transistors 201 and 202 are coupled to nodes 212 and 213, by transistors 203 and 204, respectively. The control terminals of transistors 203 and 204 are coupled to node 207, which is, in turn, coupled to power supply node 208 via resistor 214. Node 207 is further coupled to ground supply node 209 via capacitor 215. In various embodiments, capacitor 215 in conjunction with resistor 214 form a filter circuit that is configured to filter noise on power supply node 208 to maintain a stable voltage on node 207 and prevent noise from coupling into the control terminals of transistors 203 and 204. Transistors 203 and 204 can, in some embodiments, further improve the input impedance ratio between input terminals 103 and 104. Additionally, transistors 203 and 204 can reduce the capacitance between input terminal 103 and input terminal 104 of input-stage circuit 101 and node 212 and 213, which are coupled to output-stage circuit 102. Additionally, transistors 203 and 204 also reduce the capacitances between input terminals 103 and 104, and power supply node 208.

In various embodiments, the respective sizes of transistors 203 and 204 may be asymmetric in a fashion similar to the respective sizes of transistors 201 and 202. As described above, the difference in sizes may be realized by using a different number of legs for transistors 203 and 204. For example, transistor 203 may be implemented using three legs, while transistor 204 may be implemented using two legs.

Transistor 205 is coupled between node 206 and ground supply node 209, and is controlled by bias signal 216. In various embodiments, a voltage level of bias signal 216 can determine a current flowing through transistor 205. The current flowing in transistor 205 can, in some embodiments, establish an operating point for transistors 201 and 202.

Transistors 201-205 may be implemented as n-channel metal-oxide semiconductor field-effect transistors (MOSFETs), fin field-effect transistors (FinFETs), gate-all-around field-effect transistors (“GAAFETs”), bipolar junction transistors (BJTs), or any other suitable transconductance devices. Although transistors 201-205 are depicted as being single devices, in other embodiments, any of transistors 201-205 may be implemented using any suitable parallel and/or serial combination of transistors.

Resistor 214 may be implemented using polysilicon or any other suitable material available on a semiconductor manufacturing process. In some embodiments, resistor 214 may be implemented using polysilicon over p-well diffusion that is coupled to ground supply node 209 so that resistor 214 has an intrinsic capacitance to ground. Although resistor 214 is depicted as a single resistor, in other embodiments, resistor 214 may be implemented using any suitable parallel and/or series combination of resistors. Capacitor 215 may be implemented using a metal-oxide-metal (MOM) capacitor structure, a metal-insulator-metal (MIM) capacitor structure, a metal-oxide-semiconductor (MOS) capacitor structure, or any other suitable capacitor structure available on a semiconductor manufacturing process.

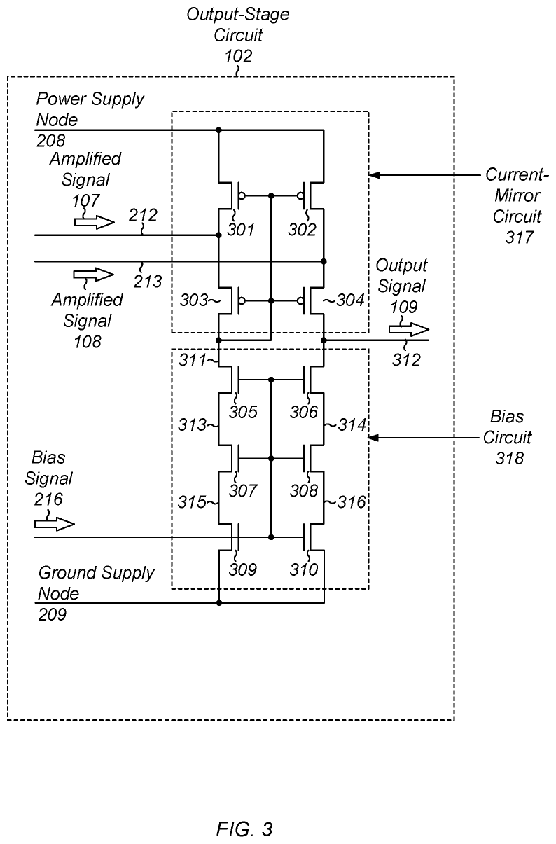

Turning to FIG. 3, a block diagram of an embodiment of output-stage circuit 102 is depicted. As illustrated, output-stage circuit 102 includes transistors 301-310. In various embodiments, transistors 301-304 may be arranged to form current-mirror circuit 317, while transistors 305-310 may be arranged to form bias circuit 318, which together with current flowing in transistor 205 is configured to determine an operating point for current-mirror circuit 317 using bias signal 216. It is noted that in some embodiments, the topology of output-stage circuit 102 may be swapped with, transistors 301-304 arranged to form bias circuit 318, and transistors 305-310 arranged to form current-mirror circuit 317.

Transistor 301 is coupled between power supply node 208 and node 212, while transistor 302 is coupled between power supply node 208 and node 213. Both transistor 301 and transistor 302 are controlled by a voltage level of node 311. In various embodiments, a ratio of the size of transistor 301 to a size of transistor 302 may be the same as a ratio of the size of transistor 201 to the size of transistor 202.

Transistor 303 is coupled between node 212 and node 311, while transistor 304 is coupled between node 213 and node 312. Both transistor 303 and transistor 304 are controlled by the voltage level of node 311. In various embodiments, a ratio of the size of transistor 303 to a size of transistor 304 may be the same as a ratio of the size of transistor 201 to the size of transistor 202. In other embodiments, respective lengths of transistors 303 and 304 may be less than respective lengths of transistors 301 and 302 to create a pseudo-cascode structure. In such cases, the head room of output-stage circuit 102 may be increased.

Transistor 305 is coupled between node 311 and node 313, while transistor 306 is coupled between node 312 and node 314. In various embodiments, a ratio of the size of transistor 305 to a size of transistor 306 may be the same as a ratio of the size of transistor 201 to the size of transistor 202. In some embodiments, to create a pseudo-cascode structure, respective lengths of transistor 305 and 306 may be less than respective channel lengths of transistors 307-310. For example, in some cases, the width to length ratio for transistor 305 and 306 may be 2.5/0.5, while the width to length ratio of transistors 307-310 may be 0.8/10 for a given leg of transistors 305-310.

Transistor 307 is coupled between node 313 and node 315, while transistor 308 is coupled between node 314 and node 316. In various embodiments, a ratio of the size of transistor 307 to a size of transistor 308 may be the same as a ratio of the size of transistor 201 to the size of transistor 202.

Transistor 309 is coupled between node 315 and ground supply node 209, while transistor 310 is coupled between node 316 and ground supply node 209. In various embodiments, a ratio of the size of transistor 309 to a size of transistor 310 may be the same as a ratio of the size of transistor 201 to the size of transistor 202.

The control (or “gate”) terminals of transistors 305-310 are coupled to bias signal 216, which adjusts the conductance of transistors 305-310 to establish an operating point for current-mirror circuit 317. Current-mirror circuit 317 forces a current flowing through transistors 302, 304, 306, 308, and 310 to have a known asymmetric relationship to a current flowing through transistors 301, 303, 305, 307, and 309. In various embodiments, the known asymmetric relationship is based on the sizes of transistors 301 and 303, relative to the sizes of transistors 302 and 304.

As amplified signals 107 and 108 modify the voltages of nodes 212 and 213, the voltages of nodes 311-316 change to maintain the relationship between the currents. In various embodiments, the voltage level of node 312, i.e., output signal 109, corresponds to a difference between amplified signal 107 and amplified signal 108, where amplified signal 107 is weighted according to the sizes of transistor 301 and 303, and amplified signal 108 is weighted according to the sizes of transistors 302 and 304.

Transistors 301-304 may be implemented as p-channel MOSFETs, FinFETs, GAAFETs, or any other suitable transconductance devices. Transistors 305-310 may be implemented as n-channel MOSFETs, FinFETs, GAAFETs, or any other suitable transconductance devices. Although transistors 301-310 are depicted as being single devices, in other embodiments, any of transistors 301-310 may be implemented using any suitable parallel and/or serial combination of transistors.

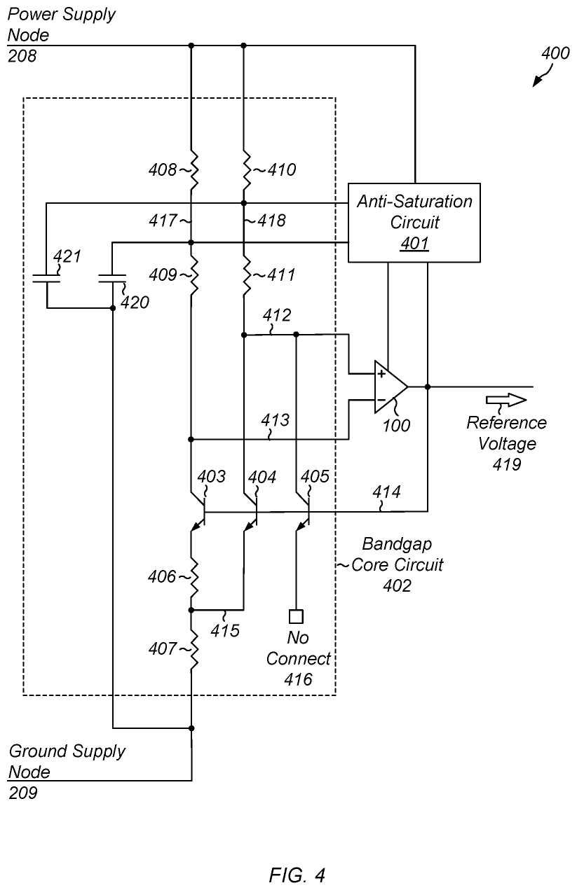

A block diagram of a voltage reference circuit is depicted in FIG. 4. As illustrated, voltage reference circuit 400 includes amplifier circuit 100, anti-saturation circuit 401, and bandgap core circuit 402, which includes bipolar devices 403-405, resistors 406-411, and capacitors 420 and 421. In various embodiments, voltage reference circuit 400 may be an embodiment of a Brokaw bandgap reference circuit configured to generate a power supply and temperature invariant reference voltage by summing a proportional-to-absolute-temperature (“PTAT”) voltage and a complementary-to-absolute-temperature (“CTAT”) voltage.

Bandgap core circuit 402 is configured to provide respective voltage levels on node 412 and 413 using reference voltage 419. To provide the respective voltage levels on nodes 412 and 413, bandgap core circuit 402 employs bipolar devices 403-405, and resistors 406-411. A collector terminal of bipolar device 403 is coupled to node 413, while an emitter terminal of bipolar device 403 is coupled to resistor 406. In a similar fashion, a collector terminal of bipolar device 404 is coupled to node 412, while an emitter terminal of bipolar device 404 is coupled to node 415. The base terminals of bipolar devices 403 and 404 are coupled to node 414 onto which amplifier circuit 100 provides reference voltage 419. The emitter areas of bipolar devices 403 and 404 may, in various embodiments, be different. For example, the emitter area of bipolar device 403 may be twice the emitter area of bipolar device 404.

In various embodiments, bipolar device 403 is configured, using reference voltage 419, to sink a first current from node 413, while bipolar device 404 is configured, using reference voltage 419, to sink a second current from node 412. In some embodiments, a value of the first current may be different than a value of the second current. The respective values of the currents flowing in bipolar devices 403 and 404 are based on the ratio of a sum of the values of resistors 408 and 409 to a sum of the values of resistors 410 and 411. In various embodiments, amplifier circuit 100 is part of a regulation loop configured to regulate reference voltage 419 to minimize the difference between the voltage levels of node 412 and 413. In other words, a voltage drop across the combination of resistors 408 and 409 should be the same as a voltage drop across the combination of resistors 410 and 411. In cases where the voltage drop across the combination of resistors 408 and 409 is not the same as the voltage drop across the combination of resistors 410 and 411 are not the same, the currents flowing in bipolar devices 403 and 404 will be different. In various embodiments, the ratio of the emitter areas of bipolar devices 403 and 404 together with their respective currents, create a delta base-to-emitter voltage across resistor 406. The respective values of the current may be based, at least in part, on the respective emitter areas of bipolar devices 403 and 404.

A collector terminal of bipolar device 405 is also coupled to node 412, while an emitter terminal of bipolar device 405 is coupled to no connect 416, indicating that it is not connected to any other circuit elements. In various embodiments, bipolar device 405 is a “dummy device” added to voltage reference circuit 400 to balance the leakage currents on nodes 412 and 413 through the collector-to-substrate junctions of transistors 403 and 404. In some cases, bipolar device 405 may remediate, at least in part, lithographic defects in bipolar devices 403 and 404 during manufacture, temperature gradient effects on an integrated circuit, mechanical stress, and the like. To reduce such lithographic defects, bipolar devices 403-405 may be arranged in a row with two instances of bipolar device 403 located on either side of transistor 404, and two instances of dummy bipolar device 405 may be arranged next to each of the two instances of bipolar device 403.

Bipolar devices 403-405 may be implemented as vertical NPN bipolar junction transistors (BJTs), or any other suitable bipolar transistors. In various embodiments, the collector terminals of bipolar devices 403-405 may be isolated from a ground P-type epitaxial layer by a reverse polarized junction diode.

Resistor 406 is coupled between the emitter terminal of bipolar device 403 and node 415. Resistor 407 is coupled between node 415 and ground supply node 209 forming a resistive voltage divider circuit. Since the emitter terminal of bipolar device 404 is coupled to node 415, the base-to-emitter voltages of bipolar devices 403 and 404 can be different. The difference in the base-to-emitter voltages of bipolar devices 403 and 404 create a PTAT voltage across resistor 406, which results in a PTAT current that flows through resistor 407 based on the respective emitter currents of bipolar devices 403 and 404. The voltage across resistor 407 is a PTAT voltage which is combined on node 415 with the CTAT voltage of the base-to-emitter voltage of bipolar device 404. The resulting sum of PTAT and CTAT voltages on node 414 provides the desired temperature independence.

Resistor 408 is coupled between power supply node 208 and node 417. In a similar fashion, resistor 410 is coupled between power supply node 208 and node 418. Resistor 409 is coupled between node 417 and node 413, while resistor 411 is coupled between node 418 and node 412. In various embodiments, resistors 408 and 409 form a first resistor network, while resistors 410 and 411 form a second resistor network. As used herein, a resistor network refers at least two resistors coupled together in any suitable series and/or parallel arrangement.

Resistors 406-411 may be implemented using polysilicon or any other suitable material available on a semiconductor manufacturing process. In some embodiments, resistors 406-411 may be implemented using polysilicon over p-well diffusion that is coupled to ground supply node 209 so that resistors 406-411 have an intrinsic capacitance to ground. Although resistors 406-411 are depicted as single resistors, in other embodiments, any of resistors 406-411 may be implemented using any suitable parallel and/or series combination of resistors.

As noted above, noise from power supply node 208 can couple into nodes 412 and 413 via resistors 408-411. Due to the difference in emitter areas of bipolar devices 403-405, respective capacitance values of nodes 412 and 413 can be different, resulting in different time constants for the two nodes. The different time constants of nodes 412 and 413 can result in the noise from power supply node 208 behaving differently on the two nodes, resulting in common-mode disturbances becoming differential disturbances, which can affect the value of reference voltage 419.

Capacitor 420 is coupled between node 417 and ground supply node 209. In a similar fashion, capacitor 421 is coupled between node 418 and ground supply node 209. In various embodiments, a ratio of a value of capacitor 421 to a value of capacitor 420 may be the same as the ratio of the size of transistor 201 to the size of transistor 202. In various embodiments, capacitors 420 and 421, along with resistors 408-411 form filters circuits that filter noise from power supply node 208 on nodes 417 and 418. Capacitors 420 and 421 may be implemented using a MOM capacitor structure, a MIM capacitor structure, a MOS capacitor structure, or any other suitable capacitor structure available on a semiconductor manufacturing process.

Amplifier circuit 100 is configured to generate reference voltage 419 using the respective voltage levels of nodes 412 and 413. As illustrated, node 412 is coupled to input terminal 103 of amplifier circuit 100, and node 413 is coupled to input terminal 104 of amplifier circuit 100. To generate reference voltage 419, amplifier circuit 100 is configured, using closed-loop feedback through transistors 403 and 404, to adjust a value of reference voltage 419 so as to minimize a difference between the respective voltage levels of nodes 412 and 413. In various embodiments, the difference between the respective voltage levels of nodes 412 and 413 may be as close to zero voltages as the tolerance of amplifier circuit 100, variations in circuit element values, and the like, will allow.

In various embodiments, values for resistor 409 and resistor 411 are selected such that the time constants of nodes 412 and 413 are substantially the same excluding the input capacitances of amplifier circuit 100. For example, the time constant of node 413, 1413, can be determined using Equation 1, where R is a base value for both resistors 409 and 411, and C is a base capacitance of nodes 412 and 413.

$${τ}_{413} = \frac{R}{2} \cdot 2 C = RC \qquad ( 1 )$$

In a similar fashion, the time constant of node 412, can be determined using Equation 2. It is noted that the base capacitance value is scaled differently in Equation 1 and Equation 2, due to the different sizes of bipolar devices 403, 404, and the inclusion of dummy bipolar device 405.

$${τ}_{412} = \frac{R}{3} \cdot 3 C = RC \qquad ( 2 )$$

In both cases, the time constant reduces to RC. When the input capacitance of a symmetric amplifier circuit is added, however, the time constants of nodes 412 and 413 are no longer the same. For example, the time constant of node 413 with the input capacitance of the symmetric amplifier circuit can be determined using Equation 3, where Cₐₘₚ is the capacitance of both input terminals of the symmetric amplifier circuit.

$${τ}_{413} = \frac{R}{2} \cdot ( 2 C + {C}_{amp} ) = RC + \frac{R}{2} {C}_{amp} \qquad ( 3 )$$

In a similar fashion, the time constant of node 412 can be determined using Equation 4. With the addition of the input capacitances of the symmetric amplifier circuit, the two time constants are no longer equal, which can result in noise from power supply node 209 being treated as differential disturbances by the symmetric amplifier circuit.

$${τ}_{412} = \frac{R}{3} \cdot ( 3 C + {C}_{amp} ) = RC + \frac{R}{3} {C}_{amp} \qquad ( 4 )$$

As described above, amplifier circuit 100 can be designed with different input impedances and, therefore, capacitances. By selecting different multiples of a unit capacitance for the input transistors of amplifier circuit 100 (e.g., transistors 201 and 202) for the input terminal capacitances of amplifier circuit 100, the time constants for nodes 412 and 413 can be made to match as show in Equations 5 and 6, where Cᵤₙᵢₜ is the unit capacitance of a single leg of either transistor 201 or 202.

$${τ}_{413} = \frac{R}{2} \cdot ( 2 C + 2 {C}_{unit} ) = R ( C + {C}_{unit} ) \qquad ( 5 )$$

$${τ}_{412} = \frac{R}{3} \cdot ( 3 C + 3 {C}_{unit} ) = R ( C + {C}_{unit} ) \qquad ( 6 )$$

By compensating for the difference in the respective capacitances of nodes 412 and 413, the respective time constants of nodes 412 and 413 can be made similar so to prevent noise from power supply node 209 becoming differential disturbances that can affect the value of reference voltage 419.

Anti-saturation circuit 401 is configured to modify the voltage levels of nodes 417 and 418, and, subsequently, the voltage levels of nodes 412 and 413, using reference voltage 419. As described below, anti-saturation circuit 401 may additionally use corresponding voltage levels of internal nodes of amplifier circuit 100 to modify the voltage levels of nodes 417 and 418. In various embodiments, by modifying the voltage levels of nodes 417 and 418, as well as nodes 412 and 413, the operation of bipolar devices 403 and 404 can be maintained in the linear region, thereby improving performance for low voltage values of power supply node 208.

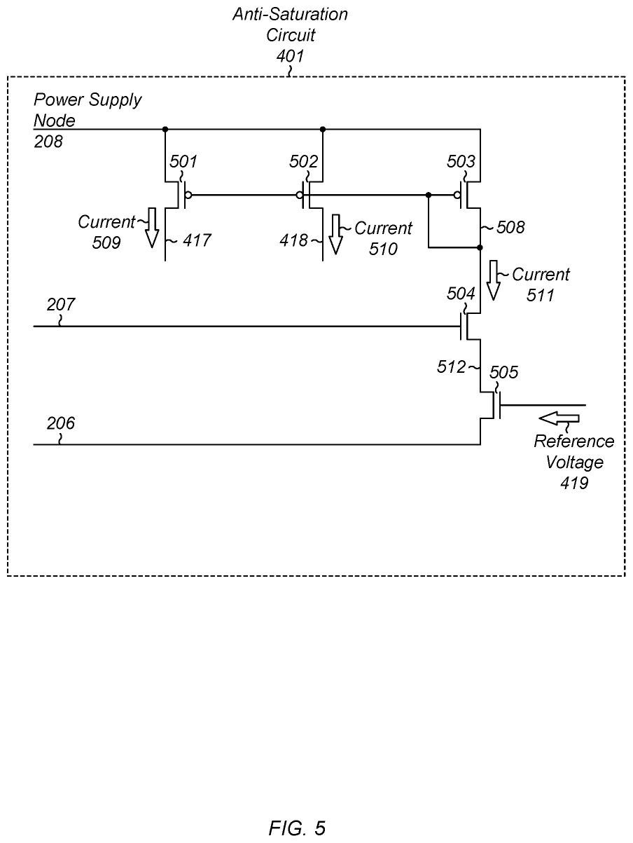

Turning to FIG. 5, a block diagram of an embodiment of anti-saturation circuit 401 is depicted. As illustrated, anti-saturation circuit 401 includes transistors 501-505.

Transistor 501 is coupled between power supply node 208 and node 417, while transistor 502 is coupled between power supply node 208 and node 418. Both transistor 501 and transistor 502 are controlled by a voltage level of node 508. In various embodiments, a ratio of a size of transistor 501 to a size of transistor 502 may be the same as a ratio of a size of transistor 201 to a size of transistor 202.

Transistor 503 is coupled between power supply node 208 and node 508, and is controlled by the voltage level of node 508. In various embodiments, transistor 503 in combination with transistors 501 and 502 form a current mirror circuit, with transistors 501 and 502 replicating or “mirroring” current 511 to generate currents 509 and 510, respectively. In some embodiments, the respective values of currents 509 and 510 may be scaled, up or down, from a value of current 511 based on the respective sizes of transistors 501 and 502 relative to a size of transistor 503.

Transistor 504 is coupled between node 508 and node 512, and is controlled by a voltage level of node 207. Transistor 505 is coupled between node 512 and node 206, and is controlled by reference voltage 419. In various embodiments, the respective voltage levels of nodes 207 and 206, along with reference voltage 419, determine a value for current 511.

Transistors 501-503 may be implemented as p-channel MOSFETs, FinFETs, GAAFETs, or any other suitable transconductance devices, such as BJTs. Transistors 504 and 505 may be implemented as n-channel MOSFETs, FinFETs, GAAFETs, or any other suitable transconductance devices, such as BJTs. Although transistors 501-505 are depicted as being single devices, in other embodiments, any of transistors 501-505 may be implemented using any suitable parallel and/or serial combination of transistors.

In various embodiments, transistor 505 is configured to detect a level of reference voltage 419 by generating a voltage on node 512, which is cascoded by transistor 504 to generate current 511. As described above, current 511 is then mirrored to generate currents 509 and 510, which are sourced to nodes 417 and 418, respectively.

In various embodiments, when the collector-to-base voltages of transistors 403 and 404 approach zero volts, transistor 505 begins to conduct, ultimately generating current 511. As currents 509 and 510 are sourced to nodes 417 and 418, the voltage levels on node 417 and 418 increase, thereby decreasing the respective voltage drops across resistors 408 and 410. The increase in the voltage levels of node 417 and 419 also increase the voltage levels of node 413 and 412, via resistors 409 and 411, respectively, which increases the voltage levels of the collector terminals of transistors 403 and 404, helping to maintain the desired regime of operation.

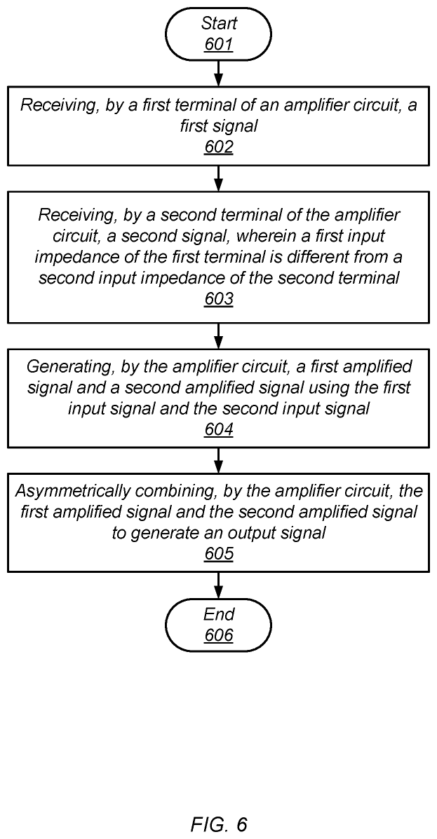

Turning to FIG. 6, a flow diagram depicting an embodiment of a method for operation of an asymmetric amplifier circuit is illustrated. The method, which may be applied to various asymmetric amplifier circuits, e.g., asymmetric amplifier circuit 100 as depicted in FIG. 1, begins in block 601.

The method includes receiving, by a first terminal of an amplifier circuit, a first signal (block 602). The method also includes receiving, by a second terminal of the amplifier circuit, a second signal (block 603). In various embodiments, a first input impedance of the first terminal is different from a second input impedance of the second terminal.

The method further includes generating, by the amplifier circuit, a first amplified signal and a second amplified signal using the first input signal and the second input signal (block 604). In various embodiments, the amplifier circuit includes an input-stage circuit and an output-stage circuit. In such cases, generating the first amplified signal and the second amplified signal may include generating, using a first transistor included in the input-stage circuit, the first amplified signal using the first input signal, and generating, using a second transistor included in the input-stage circuit, the second amplified signal using the second input signal. In various embodiments, a first size of the first transistor is different than a second size of the second transistor.

In some embodiments, the method may further include coupling, by a third transistor and a fourth transistor, the input-stage circuit to the output-stage circuit. In some cases, a third size of the third transistor is different than a fourth size of a fourth transistor. In various embodiments, a first ratio of the first size of the first transistor to the second size of the second transistor is the same as a second ratio of the third size of the third transistor to the fourth size of the fourth transistor.

The method also includes asymmetrically combining, by the amplifier circuit, the first amplified signal and the second amplified signal to generate an output signal (block 605). In various embodiments, the output signal may correspond to reference voltage 419 as depicted in the embodiment of FIG. 4.

In some embodiments, the method may also include generating, by bandgap core circuit 402, the first signal using reference voltage 419, and generating, by bandgap core circuit 402, the second signal using the reference voltage 419. In various embodiments, bandgap core circuit 402 includes a plurality of bipolar devices including a bipolar device 403 with a first emitter area coupled to the first input terminal of the amplifier circuit 100, and bipolar device 404 with a second emitter area coupled to the second input terminal of amplifier circuit 100. In some embodiments, the first emitter area is different than the second emitter area.

The method may, in various embodiments, included coupling, via resistors 408 and 409, the first terminal of the amplifier circuit to power supply node 208, and coupling, via resistors 410 and 411, the second terminal of amplifier circuit 100 to power supply node 208. Additionally, the method may include coupling a first emitter terminal of the bipolar device 403 to a first voltage level, and coupling a second emitter terminal of bipolar device 404 to a second voltage level different than the first voltage level. In various embodiments, the method may include generating the first voltage level and the second voltage level using a resistive voltage divider formed from resistors 406 and 407.

In various embodiments, the method may further include adjusting, by anti-saturation circuit 401, respective values of the first input signal and the second input signal based on a voltage level of reference voltage 419. The method concludes in block 606.

The present disclosure includes references to “an embodiment” or groups of “embodiments.” As used herein, embodiments are different implementations of instances of the disclosed concepts. References to “an embodiment,” “some embodiments,” and the like do not necessarily refer to the same embodiment. Many embodiments are possible and contemplated, including those specifically disclosed as well as modifications or alternatives that fall within the spirit or scope of the disclosure.

The above disclosure is meant to illustrate some of the principles and various embodiments of the disclosed concepts. Numerous variations and modifications will become apparent to those skilled in the art once the above disclosure is fully appreciated. It is intended that the following claims be interpreted to embrace all such variations and modifications.

What is claimed is:

1. An apparatus, comprising:
an input-stage circuit that includes a first terminal with a first input impedance and a second terminal with a second input impedance different than the first input impedance, where the input-stage circuit is configured to:
receive a first input signal via the first input terminal;
receive a second input signal via the second input terminal; and
generate a first amplified signal and a second amplified signal using the first input signal and the second input signal, respectively; and
an output-stage circuit configured to asymmetrically combine the first amplified signal and the second amplified signal to generate an output signal.

2. The apparatus of claim 1, wherein the input-stage circuit includes:
a first transistor with a first control terminal coupled to the first input terminal; and
a second transistor with a second control terminal coupled to the second input terminal, wherein a first size of the first transistor is different than a second size of the second transistor.

3. The apparatus of claim 2, wherein the input-stage circuit further includes:
a third transistor coupled between the first transistor and the output-stage circuit; and
a fourth transistor coupled between the second transistor and the output-stage circuit, wherein a third size of the third transistor is different than a fourth size of the fourth transistor.

4. The apparatus of claim 3, wherein a first ratio of the first size of the first transistor to the second size of the second transistor is the same as a second ratio of the third size of the third transistor to the fourth size of the fourth transistor.

5. The apparatus of claim 2, wherein the output-stage circuit includes a current-mirror circuit that includes a third transistor and a fourth transistor, and wherein to asymmetrically combine the first amplified signal and the second amplified signal, the output-stage circuit is further configured to generate, using the current-mirror circuit, a first current and a second current whose values are based on respective sizes of the third transistor and the fourth transistor.

6. The apparatus of claim 5, wherein the output-stage circuit further includes a bias circuit configured to bias the current-mirror circuit using a bias signal.

7. A method, comprising:
receiving, by a first input terminal of an amplifier circuit, a first input signal;
receiving, by a second input terminal of the amplifier circuit, a second input signal, wherein a first input impedance of the first input terminal is different from a second input impedance of the second input terminal;
generating, by the amplifier circuit, a first amplified signal and a second amplified signal using the first input signal and the second input signal; and
asymmetrically combining, by the amplifier circuit, the first amplified signal and the second amplified signal to generate an output signal.

8. The method of claim 7, wherein the amplifier circuit includes an input-stage circuit and an output-stage circuit, and wherein generating the first amplified signal and the second amplified signal includes:
generating, using a first transistor included in the input-stage circuit, the first amplified signal using the first input signal; and
generating, using a second transistor included in the input-stage circuit, the second amplified signal using the second input signal, wherein a first size of the first transistor is different from a second size of the second transistor.

9. The method of claim 8, further comprising coupling, by a third transistor and a fourth transistor, the input-stage circuit to the output-stage circuit, wherein a third size of the third transistor is different than a fourth size of the fourth transistor.

10. The method of claim 9, wherein a first ratio of the first size of the first transistor to the second size of the second transistor is the same as a second ratio of the third size of the third transistor to fourth size of the fourth transistor.

11. The method of claim 7, further comprising:
generating, by a core circuit, the first input signal using the output signal, wherein the core circuit includes a plurality of bipolar devices; and
generating, by the core circuit, the second input signal using the output signal.

12. The method of claim 11, wherein generating the first input signal includes sinking, by a first bipolar device using the output signal, a first current from a first circuit node coupled to the first input terminal of the amplifier circuit, and wherein generating the second input signal includes sinking, by a second bipolar device using the output signal, a second current from a second circuit node coupled to the second input terminal of the amplifier circuit, wherein a first emitter area of the first bipolar device is different than a second emitter area of the second bipolar device.

13. The method of claim 12, wherein a first base-emitter voltage of the first bipolar device is different from a second base-emitter voltage of the second bipolar device.

14. A voltage reference circuit, comprising:
a bandgap core circuit that includes a plurality of bipolar devices, wherein the bandgap core circuit is configured to:
provide a first voltage level to a first circuit node using a reference voltage; and
provide a second voltage level to a second circuit node using the reference voltage; and
an amplifier circuit that includes a first input terminal coupled to the first circuit node and a second input terminal coupled to the second circuit node, wherein a first input impedance of the first input terminal is different from a second input impedance of the second input terminal, and wherein the amplifier circuit is configured to generate the reference voltage using the first voltage level of the first circuit node and the second voltage level of the second circuit node.

15. The voltage reference circuit of claim 14, wherein the amplifier circuit includes:
a first transistor with a first control terminal coupled to the first input terminal; and
a second transistor with a second control terminal coupled to the second input terminal, wherein a first size of the first transistor is different from a second size of the second transistor.

16. The voltage reference circuit of claim 15, wherein to generate the reference voltage, the amplifier circuit is further configured to:
generate, using the first transistor and the first voltage level of the first circuit node, a first amplified signal; and
generate, using the second transistor and the second voltage level of the second circuit node, a second amplified signal.

17. The voltage reference circuit of claim 16, wherein the amplifier circuit further includes a current-mirror circuit that includes a third transistor and a fourth transistor, wherein the current-mirror circuit is configured to generate the reference voltage using the first amplified signal and the second amplified signal, and wherein a first ratio of the first size of the first transistor to the second size of the second transistor is the same as a second ratio of a third size of the third transistor to a fourth size of the fourth transistor.

18. The voltage reference circuit of claim 14, wherein a first collector terminal of a first bipolar device of the plurality of bipolar devices is coupled to the first circuit node, wherein a second collector terminal of a second bipolar device of the plurality of bipolar devices is coupled to the second circuit node, wherein a first base terminal of the first bipolar device and a second base terminal of the second bipolar device are coupled to the reference voltage, and wherein a first emitter area of the first bipolar device is different from a second emitter area of the second bipolar device.

19. The voltage reference circuit of claim 18, wherein the bandgap core circuit includes:
a first resistor network configured to couple the first circuit node to a power supply node; and
a second resistor network configured to couple the second circuit node to the power supply node.

20. The voltage reference circuit of claim 14, further comprising an anti-saturation circuit configured to adjust, using the reference voltage, the first voltage level and the second voltage level, and wherein the first voltage level is the same as the second voltage level.
